(19) United States
(12) Patent Application Publication
(10) Pub. No.: US 2008/0291654 A1
(43) Pub. Date: Nov. 27, 2008

(54) WIRELESS COMMUNICATION NODULE ASSEMBLY

(75) Inventors: Kuo-Hsien Liao, Taichung City (TW); Kuan-Hsing Li, Taichung City (TW); Jia-Yang Chen, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: Universal Scientific Industrial Co., LTD., Nan Tou (TW)

(21) Appl. No.: 11/943,421

(22) Filed: Nov. 20, 2007

(30) Foreign Application Priority Data
May 22, 2007 (TW) 96208174

(51) Int. Cl. H05K 9/00

(52) U.S. Cl. 361/818

(57) ABSTRACT

A wireless communication module assembly includes a main board having a top surface on which a plurality of grounding pads are provided, a circuit board unit, and a metal cap. The circuit board unit has a bottom surface electrically mounted on the top surface of the main board, a top surface with a plurality of grounding pads, and a plurality of notches corresponding to the grounding pads of the main board. The metal cap covers the circuit board unit and has first mounting legs respectively and electrically connected with the grounding pads of the circuit board unit, and second mounting legs respectively passing through the notches of the circuit board unit and electrically connected with the grounding pads of the main board.

### BACKGROUND OF THE INVENTION

1. Field of the Invention

The present invention relates generally to a communication module and more particularly, to a wireless communication module assembly that can minimize the electromagnetic interference (hereinafter referred to as “EMI”).

2. Description of the Related Art

FIG. 1 illustrates a wireless communication module assembly, denoted by reference numeral 1, according to a prior art. According to this design, the communication module assembly 1 includes a main board 2 provided with a grounding mechanism, a substrate 3 which is grounded by means of electrically connecting the main board 2, and a metal cap 4. The substrate 3 has a plurality of grounding pads 5 and a plurality of grounding via holes (not shown), through which the metal cap 4 is indirectly connected to the grounding mechanism of the main board 2 such that the metal cap 4 is grounded. According to this design, the grounding via holes tend to produce parasitic inductance and resistance, resulting in a poor grounding effect of the metal cap. Therefore, the wireless communication module assembly 1 cannot be well grounded to effectively isolate the electromagnetic interference (EMI).

Further, in the aforesaid wireless communication module assembly 1, the main board 2 has a heat-dissipative mechanism, and the substrate 3 is formed of a stack of boards. Each board of the substrate 3 has a plurality of through holes for guiding heat from the chips on the substrate 3 to the main board 2 for further dissipation. Because the thermal conductivity of air is only about 0.025 W/m·K and the substrate 3 is directly stacked on the main board 2 such that air convection can hardly exists between the main board 2 and the substrate 3, hot air cannot be quickly discharged out of the wireless communication module assembly 1 and tends to be accumulated within the wireless communication module assembly 1. Therefore, this design of the conventional wireless communication module assembly 1 has the drawback of poor heat-dissipative effect.

Therefore it is desirable to provide a wireless communication module assembly that eliminates the aforesaid problems.

### SUMMARY OF THE INVENTION

The present invention has been accomplished in view of the above-noted circumstances. It is the primary objective of the present invention to provide a wireless communication module assembly, which can provide a good grounding effect to effectively minimize the electromagnetic interference.

It is another objective of the present invention to provide a wireless communication module assembly, which can provide a good heat-dissipative effect.

To achieve above-mentioned objectives of the present invention, the wireless communication module assembly comprises a main board, circuit board unit, and a metal cap. The main board has a top surface on which a plurality of grounding pads are provided. The circuit board unit has a bottom surface electrically mounted on the top surface of the main board, a top surface with a plurality of grounding pads, and a plurality of notches corresponding to the grounding pads of the main board. The metal cap covers the circuit board unit and has first mounting legs respectively and electrically connected with the grounding pads of the circuit board unit, and second mounting legs respectively passing through the notches of the circuit board unit and electrically connected with the grounding pads of the main board.

As indicated above, the wireless communication module assembly provided by the present invention has the metal cap directly and electrically connected to the main board and grounded with the main board so as to prevent the parasitic capacitance and resistance, improving the grounding effect and reducing the electromagnetic interference. In addition, the metal cap can directly dissipate a part of the thermal energy produced during operation of the circuit board unit to ambiance and conduct the other part of the produced thermal energy to the main board for further dissipation by a heat-dissipative system of the main board, thereby eliminating the drawback of poor heat dissipation effect of the prior art design. Compared to the prior art design, the invention greatly improves the grounding effect and heat dissipation effect of the communication module.

In a preferred embodiment of the present invention, the circuit board unit includes a substrate and at least one IC chip. The substrate has a top surface forming the top surface of the circuit board unit, a bottom surface forming the bottom surface of the circuit board unit, and a periphery provided with the notches aimed at the grounding pads of the main board. The at least one chip is provided on the top surface of the substrate.

In another preferred embodiment of the present invention, the circuit board unit includes a spacer, a substrate and at least one IC chip. The spacer has a top bearing face, a bottom bearing face served as the bottom surface of the circuit board unit and electrically bonded to the main board, an opening through the top bearing face and the bottom bearing face, and a plurality of notches at a periphery thereof corresponding to the grounding pads of the main board. The substrate has a top surface served as the top surface of the circuit board unit, a bottom surface electrically connected with the top bearing face of the spacer, and a plurality of notches aligned with the notches of the spacer. The notches of the spacer and the substrate form the notches of the circuit board unit. The at least one IC chip includes a chip electrically mounted on the bottom surface of the substrate and received in the opening of the spacer.

In still another preferred embodiment of the present invention, the circuit board unit comprises a first spacer, a first substrate, a second spacer, a second substrate and a plurality of chips. The first spacer has a top bearing face, a bottom bearing face served as the bottom surface of the circuit board unit and electrically bonded to the main board, an opening through the top bearing face and bottom bearing face, and a plurality of notches corresponding to the grounding pads of the main board. The first substrate has a top surface, a bottom surface electrically bonded to the top bearing face of the first spacer, and a plurality of notches aligned with the notches of the first spacer. The second spacer has a top bearing face, a bottom bearing face electrically bonded to the top surface of the first substrate, an opening through the top bearing face and the bottom bearing face thereof, and a plurality of notches aligned with the notches of the first substrate. The second substrate has a top surface served as the top surface of the circuit board unit, a bottom surface electrically bonded to the top bearing face of the second spacer, and a plurality of notches aligned with the notches of the second spacer. The aligned notches of the first spacer, the first substrate, the second spacer and the second substrate form the notches of the circuit board unit. The plurality of IC chips include a first chip electrically mounted on the bottom surface of the first substrate and received in the opening of the first spacer and a second chip electrically mounted on the bottom surface of the second substrate and received in the opening of the second spacer.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a perspective view of a wireless communication module assembly according to a prior art;

FIG. 2 is an exploded view of a wireless communication module assembly in accordance with a first embodiment of the present invention;

FIG. 3 is a perspective view of the wireless communication module assembly in accordance with the first embodiment of the present invention;

FIG. 4 is a sectional view taken along line 4-4 of FIG. 3;

FIG. 5 is an exploded view of a wireless communication module assembly in accordance with a second embodiment of the present invention;

FIG. 6 is a perspective view of the wireless communication module assembly in accordance with the second embodiment of the present invention;

FIG. 7 is a sectional view taken along line 7-7 of FIG. 6, and

FIG. 8 is a schematic sectional view of a wireless communication module assembly in accordance with a third embodiment of the present invention.

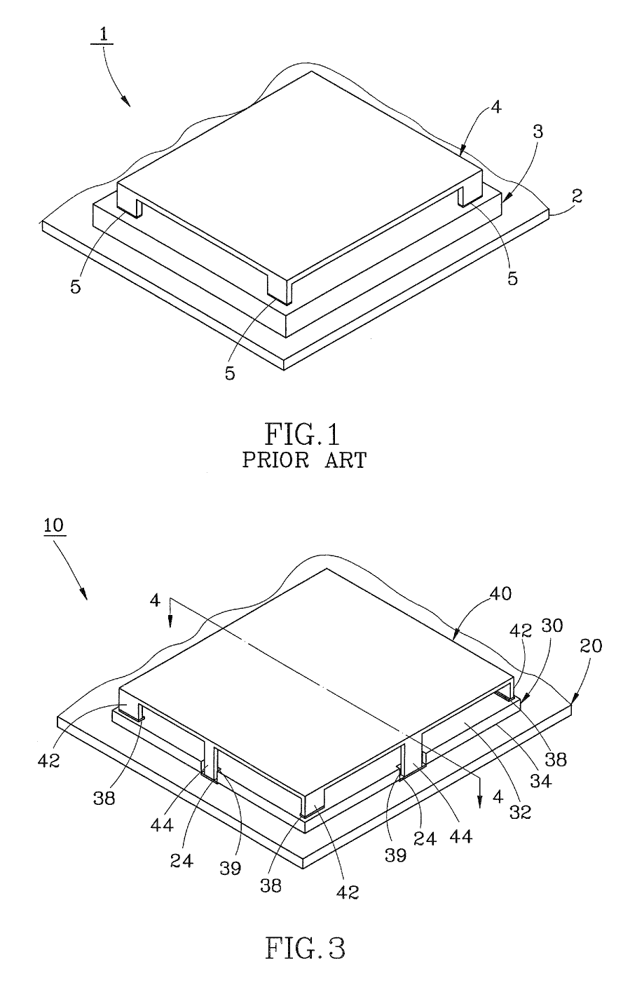

### DETAILED DESCRIPTION OF THE INVENTION

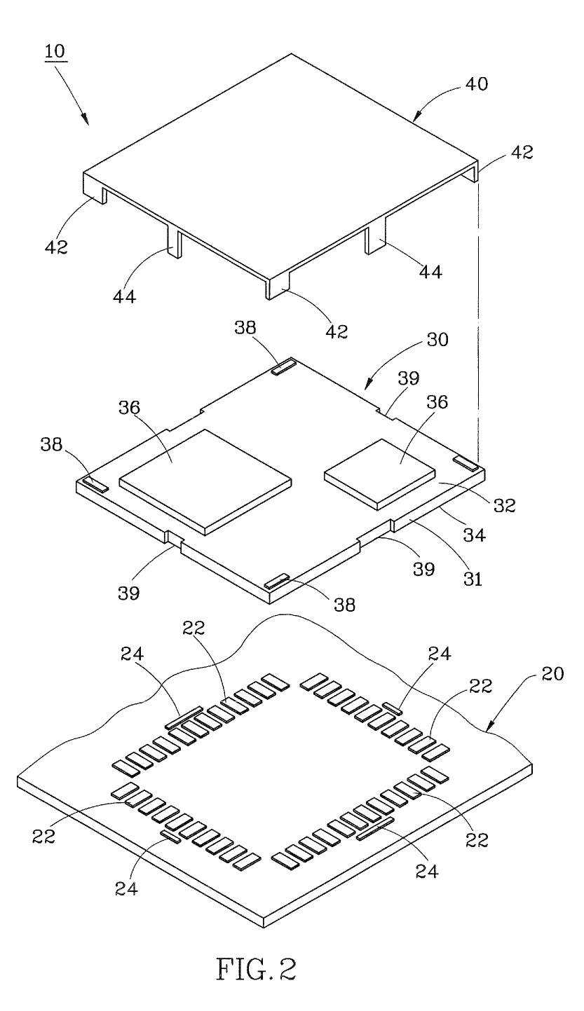

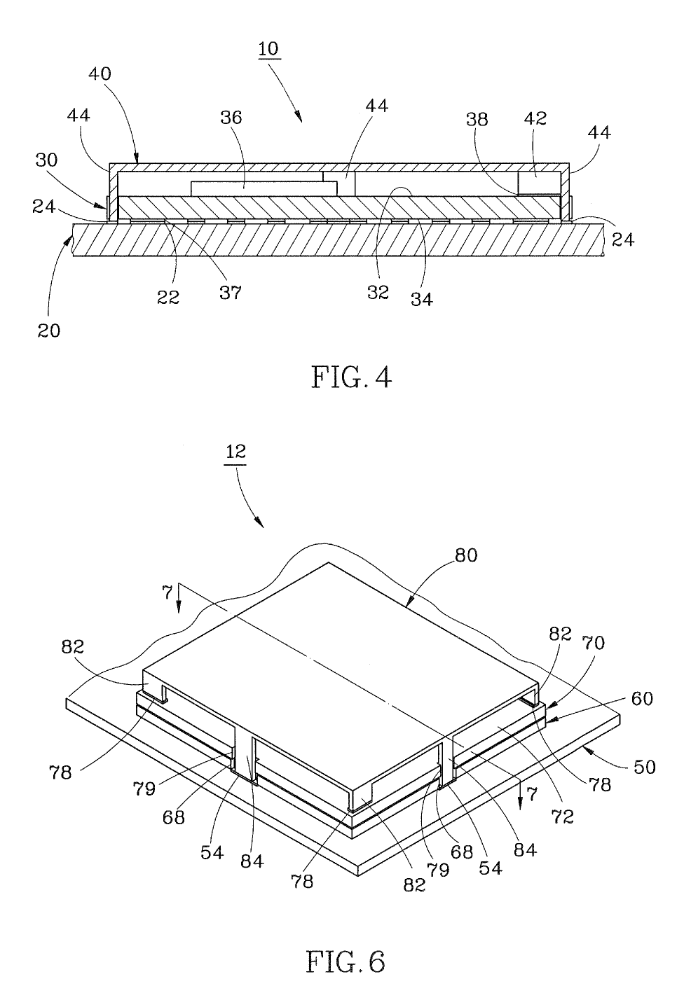

As shown in FIGS. 2-4, a wireless communication module assembly 10 in accordance with a first embodiment of the present invention comprises a main board 20, a circuit board unit 30 including a substrate 31, and a metal cap 40.

The main board 20 has arranged a plurality of contact pads 22 and grounding pads 24 on its top surface.

The substrate 31 of the circuit board unit 30 has a top surface 32, a bottom surface 34, a plurality of contact pads 37 at the bottom surface 34, a plurality of grounding pads 38 at the top surface 32 and a plurality of notches 39 at a periphery thereof. The circuit board unit 30 further includes two chips 36 mounted on the top surface 32 of the substrate 31. It is to be easily understood that the circuit board unit 30 can be designed containing one or more chips of various functions, which can be mounted on the top surface 32 and/or the bottom surface 34 of the substrate 31, depending on the requirement of the circuit board unit 30. The contact pads 37 at the bottom surface 34 of the substrate 31 are electrically connected to the contact pads 22 of the main board 20 in such a way that the notches 39 of the substrate 31 are respectively aimed at the grounding pads 24 of the main board 20.

The metal cap 40 is capped on the top side of the circuit board unit 30, having a plurality of first mounting legs 42 and a plurality of second mounting legs 44 around the border. A length of the first mounting legs 42 is smaller than the length of the second mounting legs 44. The first mounting legs 42 are respectively electrically connected to the grounding pads 38 at the top surface 32 of the substrate 31. The second mounting legs 44 are respectively electrically inserted through the notches 39 of the substrate 31 and electrically connected to the grounding pads 24 of the main board 20.

According to the aforesaid embodiment of the present invention, the wireless communication module assembly 10 has the metal cap 40 directly and electrically connected to the main board 20 and grounded with the main board 20 to prevent the parasitic capacitance and resistance, improving the grounding effect and reducing the electromagnetic interference (EMI). With respect to heat dissipation, the metal cap 40 directly dissipates a part of thermal energy from the circuit board unit 30 to ambiance and conducts the other part of thermal energy from the circuit board unit 30 to the main board 20 for further dissipation by the heat-dissipative system of the main board 20, thereby eliminating the drawback of poor heat dissipation effect of the prior art design. When compared to the prior art design, the invention greatly improves the grounding effect and heat dissipation effect of the circuit board unit.

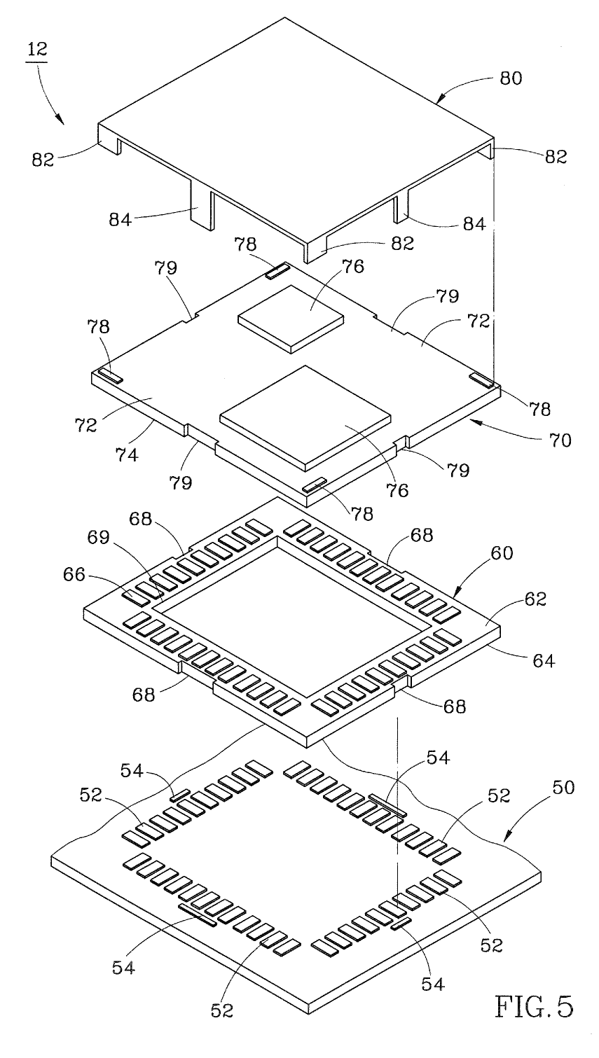

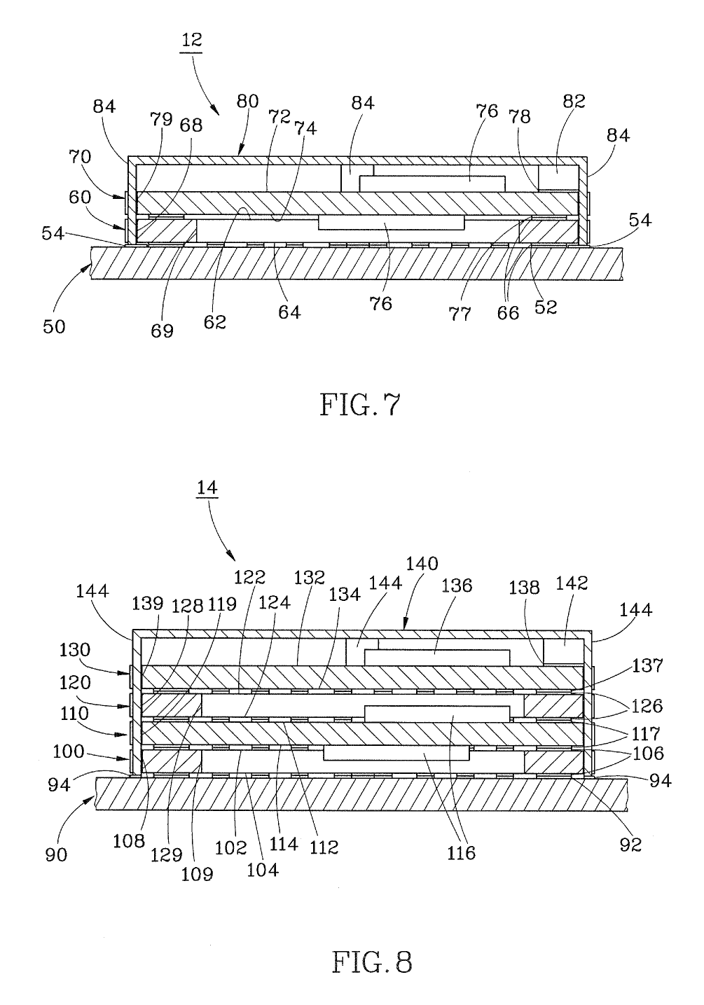

FIGS. 5-7 show a wireless communication module assembly 12 in accordance with a second embodiment of the present invention. The wireless communication module assembly 12 comprises a main board 50, a circuit board unit including a spacer 60 and a substrate 70, and a metal cap 80.

The main board 50 has arranged on its top surface a plurality of contact pads 52 and a plurality of grounding pads 54.

The spacer 60 is set in between the substrate 70 and the main board 50 and electrically connected to the substrate 70 and the main board 50. The spacer 60 has a top bearing face 62, a bottom bearing face 64, a plurality of contact pads 66, and a plurality of notches 68 at a periphery thereof. The contact pads 66 of the spacer 60 are respectively arranged on the top bearing face 62 and the bottom bearing face 64. The contact pads at the top bearing face 62 are electrically connected to the contact pads at the bottom bearing face 64. The contact pads 66 at the bottom bearing face 64 are used to be electrically connected to the contact pads 52 of the main board 50. The spacer 60 further has an opening 69 through the top bearing face 62 and the bottom bearing face 64. The notches 68 are formed on the periphery of the spacer 60 corresponding in location to the grounding pads 54 of the main board 50.

The substrate 70 has a top surface 72, a bottom surface 74, a plurality of contact pads 77, a plurality of grounding pads 78 and a plurality of notches 79. In this embodiment, the circuit board unit includes three IC chips 76, which are mounted on the top surface 72 and the bottom surface 74 of the substrate 70. However, they can be independently or simultaneously mounted on the top surface 72 and/or the bottom surface 74 according to the design requirement of the circuit board unit. The TC chip 76 at the bottom surface 74 of the substrate 70 is disposed in the opening 69 of the spacer 60. The grounding pads 78 of the substrate 70 are arranged on the top surface 72. The contact pads 77 of the substrate 70 are arranged on the bottom surface 74 and electrically connected to the contact pads 66 at the top bearing face 62 of the spacer 60. The notches 79 are formed on the periphery of the substrate 70 corresponding in location to the grounding pads 54 of the main board 50.

The metal cap 80 is capped on the top side of the substrate 70, having a plurality of first mounting legs 82 and a plurality of second mounting legs 84 around the border. A length of the first mounting legs 82 is smaller than the length of the second mounting legs 84. The first mounting legs 82 are respectively electrically connected to the grounding pads 78 at the top surface 72 of the substrate 70. The second mounting legs 174 are respectively electrically connected to the grounding pads 54 of the main board 50 through the notches 79 of the substrate 70 and the notches 68 of the spacer 60. The notches 68 of the spacer 60 have a width slightly greater than the width of the notches 79 of the substrate 70 for enabling solder wicking when electrically connecting the second mounting legs 84 of the metal cap 80 to the grounding pads 54 of the main board 50.

According to the aforesaid second embodiment, the wireless communication module assembly 12 has the metal cap 80 directly and electrically connected to the main board 50 and grounded with the main board 50 to prevent the parasitic capacitance and resistance, improving the grounding effect and reducing the electromagnetic interference (EMI). With respect to heat dissipation, the metal cap 80 directly dissipates a part of thermal energy from the circuit board unit to ambiance and conducts the other part of thermal energy from the circuit board unit to the main board 50 for further dissipation by the heat-dissipative system of the main board 50, thereby eliminating the drawback of poor heat dissipation effect of the prior art design. When compared to the prior art design, the invention greatly improves the grounding effect and heat dissipation effect of the circuit board unit. Therefore, this second embodiment achieves the same effects as the aforesaid first embodiment.

FIG. 8 illustrates a wireless communication module assembly in accordance with a third embodiment of the present invention. According to this third embodiment, the wireless communication module assembly 14 comprises a main board 90, a circuit board unit including a first spacer 100, a first substrate 110, a second spacer 120 and a second substrate 130, and a metal cap 140.

The main board 90 has arranged on its top surface a plurality of contact pads 92 and a plurality of grounding pads 94.

The first spacer 100 has a top bearing face 102, a bottom bearing face 104, a plurality of contact pads 106, and a plurality of notches 108 at a periphery thereof. The contact pads 106 of the first spacer 100 are respectively arranged on the top bearing face 102 and the bottom bearing face 104. In addition, the contact pads at the top bearing face 102 are electrically connected to the contact pads at the bottom bearing face 104. The contact pads 106 at the bottom bearing face 104 are used to be electrically connected to the contact pads 92 of the main board 90. The first spacer 100 further has an opening 109 through the top bearing face 102 and the bottom bearing face 104. The notches 108 are formed on the periphery of the first spacer 100 corresponding in location to the grounding pads 94 of the main board 90.

The first substrate 110 has a top surface 112, a bottom surface 114, a plurality of contact pads 117, and a plurality of notches 119. In this embodiment, two IC chips 116 are mounted on the top surface 112 and bottom surface 114 of the first substrate 110. It is to be understood that one or more chips can be independently or simultaneously provided on the top surface 112 and/or the bottom surface 114 of the first substrate 110, depending on the design requirement. The IC chip 116 at the bottom surface 114 of the substrate 110 is disposed in the opening 109 of the first spacer 100. The contact pads 117 of the first substrate 110 are arranged on the top surface 102 and the bottom surface 114. The contact pads 117 at the bottom surface 104 of the first substrate 110 are electrically connected to the contact pads 106 at the top bearing face 102 of the first spacer 100. The notches 119 are formed on the periphery of the first substrate 110 corresponding in location to the grounding pads 94 of the main board 90.

The second spacer 120 has a top bearing face 122, a bottom bearing face 124, a plurality of contact pads 126, and a plurality of notches 128. The contact pads 126 of the second spacer 120 are respectively arranged on the top bearing face 122 and the bottom bearing face 124. In addition, the contact pads at the top bearing face 122 are electrically connected to the contact pads at the bottom bearing face 124. The contact pads 126 at the bottom bearing face 124 are electrically connected to the contact pads 117 at the top surface 112 of the first substrate 110. The second spacer 120 further has an opening 129 through the top bearing face 122 and the bottom bearing face 124 for accommodating the IC chip 116 at the top surface 112 of the first substrate 110. The notches 128 are formed on the periphery of the second spacer 120 corresponding in location to the grounding pads 94 of the main board 90.

The second substrate 130 has a top surface 132, a bottom surface 134, a plurality of contact pads 137, a plurality of grounding pads 138, and a plurality of notches 139. In this embodiment, the circuit board unit further includes one IC chip 136 mounted on the top surface 132 of the second substrate 130. In practice, one or more IC chips can be independently or simultaneously provided on the top surface 132 and/or the bottom surface 134 of the second substrate 130. The contact pads 137 of the second substrate 130 are arranged on the bottom surface 134 of the second substrate 130 and electrically connected to the contact pads 126 at the top bearing face 122 of the second spacer 120. The notches 139 are formed on the periphery of the second substrate 130 corresponding in location to the grounding pads 94 of the main board 90.

The metal cap 140 is mounted on the top side of the second substrate 130, having a plurality of first mounting legs 142 and a plurality of second mounting legs 144 around the border. The first mounting legs 142 have a length smaller than the length of the second mounting legs 144. The first mounting legs 142 are respectively electrically connected to the grounding pads 138 at the top surface 132 of the second substrate 130. The second mounting legs 174 are respectively electrically connected to the grounding pads 94 of the main board 90 through the notches 119 and 139 of the first substrate 110 and second substrate 130 and the notches 100 and 128 of the first spacer 100 and second spacer 120. The notches 108 of the first spacer 100 have a width slightly greater than the width of the notches 119, 128 and 139 of the first substrate 110, second spacer 120 and second substrate 130 for enabling solder wicking when electrically connecting the second mounting legs 144 of the metal cap 140 to the grounding pads 94 of the main board 90.

According to the aforesaid third embodiment, the wireless communication module assembly 14 has the metal cap 140 directly and electrically connected to the main board 90 and grounded with the main board 90 to prevent the parasitic capacitance and resistance, improving the grounding effect and reducing the electromagnetic interference (EMI). With respect to heat dissipation, the metal cap 140 directly dissipates a part of thermal energy from the circuit board unit into the outside and conducts the other part of thermal energy from the circuit board unit to the main board 90 for further dissipation by the heat-dissipative system of the main board 90, thereby eliminating the drawback of poor heat dissipation effect of the prior art design. When compared to the prior art design, the invention greatly improves the grounding effect and heat dissipation effect of the circuit board unit. Therefore, this third embodiment achieves the same effects as the aforesaid first and second embodiments.

In conclusion, the invention provides a wireless communication module assembly, which has the metal cap directly and electrically connected to the main board and grounded with the main board to prevent the parasitic capacitance and resistance, improving the grounding effect and reducing the electromagnetic interference. With respect to heat dissipation, the metal cap directly dissipates a part of the thermal energy produced during operation of the circuit board unit into the outside and conducts the other part of the produced thermal energy to the main board for further dissipation by the heat-dissipative system of the main board, thereby eliminating the drawback of poor heat dissipation effect of the prior art design. When compared to the prior art design, the invention greatly improves the grounding effect and heat dissipation effect of the circuit board unit.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A wireless communication module assembly comprising:
a main board having a top surface on which a plurality of grounding pads are provided;
a circuit board unit having a bottom surface electrically mounted on the top surface of the main board, a top surface with a plurality of grounding pads, and a plurality of notches corresponding to the grounding pads of the main board; and
a metal cap covering the circuit board unit and having first mounting legs respectively and electrically connected with the grounding pads of the circuit board unit, and second mounting legs respectively passing through the notches of the circuit board unit and electrically connected with the grounding pads of the main board.

2. The wireless communication module assembly as claimed in claim 1, wherein the first mounting legs of the metal cap have a length smaller than the second mounting legs of the metal cap.

3. The wireless communication module assembly as claimed in claim 1, wherein the main board is provided on the top surface thereof with a plurality of contact pads and the circuit board unit is provided on the bottom surface thereof with a plurality of contact pads, which are respectively and electrically connected with the contact pads of the main board.

4. The wireless communication module assembly as claimed in claim 1, wherein the notches are formed on a periphery of the circuit board unit.

5. The wireless communication module assembly as claimed in claim 1, wherein the circuit board unit comprises a substrate, which has a top surface served as the top surface of the circuit board unit, a bottom surface served as the bottom surface of the circuit board unit, and a periphery provided with the notches, and a chip provided on the top surface of the substrate.

6. The wireless communication module assembly as claimed in claim 1, wherein the circuit board unit comprises:
a spacer having a top bearing face, a bottom bearing face served as the bottom surface of the circuit board unit and electrically bonded to the main board, an opening through the top bearing face and the bottom bearing face, and a plurality of notches corresponding to the grounding pads of the main board; and
a substrate having a top surface served as the top surface of the circuit board unit, a bottom surface electrically connected with the top bearing face of the spacer, and a plurality of notches aligned with the notches of the spacer to form the notches of the circuit board unit.

7. The wireless communication module assembly as claimed in claim 6, wherein the circuit board unit further comprises a chip electrically mounted on the bottom surface of the substrate and received in the opening of the spacer.

8. The wireless communication module assembly as claimed in claim 6, wherein the notches of the spacer have a width greater than the width of the notches of the substrate.

9. The wireless communication module assembly as claimed in claim 1, wherein the circuit board unit comprises:
a first spacer having a top bearing face, a bottom bearing face served as the bottom surface of the circuit board unit and electrically bonded to the main board, an opening through the top bearing face and bottom bearing face, and a plurality of notches corresponding to the grounding pads of the main board;
a first substrate having a top surface, a bottom surface electrically bonded to the top bearing face of the first spacer, and a plurality of notches aligned with the notches of the first spacer;
a second spacer having a top bearing face, a bottom bearing face electrically bonded to the top surface of the first substrate, an opening through the top bearing face and the bottom bearing face of the second spacer, and a plurality of notches aligned with the notches of the first substrate; and
a second substrate having a top surface served as the top surface of the circuit board unit, a bottom surface electrically bonded to the top bearing face of the second spacer, and a plurality of notches aligned with the notches of the second spacer;
wherein the aligned notches of the first spacer, the first substrate, the second spacer and the second substrate form the notches of the circuit board unit.

10. The wireless communication module assembly as claimed in claim 9, wherein the circuit board unit further comprises a first chip electrically mounted on the bottom surface of the first substrate and received in the opening of the first spacer and a second chip electrically mounted on the bottom surface of the second substrate and received in the opening of the second spacer.

11. The wireless communication module assembly as claimed in claim 9, wherein the notches of said first spacer have a width greater than the width of the notches of the first substrate and the second spacer and the second substrate.
